(19) United States
(12) Patent Application Publication
(10) Pub. No.: US 2025/0079156 A1
(43) Pub. Date: Mar. 6, 2025

(54) NITROGEN-BASED OXYGEN-FREE DIPOLES, RELATED DEVICES, RELATED SYSTEMS, AND RELATED METHODS

(71) Applicant: ASM IP Holding B.V., Almere (NL)

(72) Inventors: Giuseppe Alessio Verni, Vantaa (FI); Patricio Romero, Wilsele (BE); Charles Dezelah, Helsinki (FI); Suvidyakumar Vinod Homkar, Leuven (BE); Petro Deminskyi, Espoo (FI); Balaji Kannan, Phoenix, AZ (US); Michael Eugene Givens, Oud-Heverlee (BE); Mikko Leander Nisula, Espoo (FI)

(21) Appl. No.: 18/814,949

(22) Filed: Aug. 26, 2024

Related U.S. Application Data
(60) Provisional application No. 63/535,290, filed on Aug. 29, 2023.

(51) Int. Cl. H01L 21/02; C23C 16/30; C23C 16/34; C23C 16/44; C23C 16/455; C23C 16/56; H01L 21/28

(52) U.S. Cl. CPC H01L 21/02205; C23C 16/308; C23C 16/34; C23C 16/4408; C23C 16/45553; C23C 16/56; H01L 21/02175; H01L 21/0228; H01L 21/28158

(57) ABSTRACT

The technology of the present disclosure generally relates to the field of semiconductor devices. More particularly, semiconductor structures comprising a dipole layer, which comprises a metal and nitrogen containing film, and a method for producing the same. Further described are related methods, deposition systems, and devices. The method for forming the semiconductor structure comprising a dipole layer, comprises the steps of providing a substrate to a reaction chamber; contacting one or more metal precursor on at least part of the substrate by introducing the metal precursor in the reaction chamber; and reacting the deposited metal precursor with a nitrogen reactant in the reaction chamber, thereby forming a metal and nitrogen containing film on at least part of the substrate.

### CROSS-REFERENCE TO RELATED APPLICATION(S)

This application claims the benefit of U.S. Provisional Application 63/535,290 filed on Aug. 29, 2023, the entire contents of which are incorporated herein by reference.

### FIELD OF INVENTION

The present disclosure generally relates to the field of semiconductor devices. More particularly, semiconductor structures comprising a dipole layer, which comprises a metal nitride, and a method for producing the same.

### BACKGROUND OF THE DISCLOSURE

Transistors are integrated circuit components or elements that are often formed on a semiconductor substrate. Specifically, modern integrated circuits incorporate field-effect transistors (FETs) in which current flows through a semiconducting channel between a source and a drain, in response to a voltage applied to a control gate. The scaling of semiconductor devices, such as, for example, complementary metal-oxide-semiconductor (CMOS) devices, has led to significant improvements in speed and density of modern integrated circuits. In advanced CMOS devices, including central processing unit (CPU) and system-on-a-chip (SoC), structures with multiple threshold voltages are needed in order to optimize delay or power consumption. However, as device dimensions have shrunk, providing highly functional structures with multiple threshold voltages is facing serious challenges. For instance, one particular problem is controlling the threshold voltage of FETs. Therefore, there is a need to develop alternative materials to achieve better performance while scaling down.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An aspect of the present disclosure relates to a method for forming a semiconductor structure comprising a dipole layer, the method comprising the steps of:
a) providing a substrate to a reaction chamber;
b) executing one or more cycles, a cycle comprising
   i. contacting one or more metal precursor with at least a part of the substrate by introducing the one or more metal precursor in the reaction chamber; and
   ii. providing a nitrogen reactant into the reaction chamber;
thereby forming a metal and nitrogen containing film on at least part of the substrate.

In a particular embodiment, the method as disclosed herein provides that the substrate comprises at least one of an interlayer and a high-k layer, wherein the method further comprises a step of annealing the substrate, thereby forming a dipole layer.

In a particular embodiment, the method as disclosed herein provides that the metal and nitrogen containing film is formed on the interlayer.

In a particular embodiment, the method as disclosed herein provides that the metal and nitrogen containing film is formed on the high-k layer.

In a particular embodiment, the method as disclosed herein provides that the cycle further comprises a step of providing an oxygen reactant into the reaction chamber, forming a metal, oxygen, and nitrogen containing film on at least part of the substrate.

In a particular embodiment, the method as disclosed herein provides that the one or more metal precursor comprises an element chosen from the group consisting of Mg, Ca, Sr, Ba, Al, Ga, In, Sc, Y, La, Ce, Pr, Nd, Pm, Sm, Eu, Gd, Tb, Dy, Ho, Er, Tm, Yb, Lu, Ti, Zr, Hf, V, Nb, Ta, Cr, Mo, Re, Ge, Sb, Zn, and W.

In a particular embodiment, the method as disclosed herein provides that the one or more metal precursor comprises a ligand chosen from the group consisting of an amine, alkenyl, carbonyl, alkoxide, beta-diketone, diazadiene, amidinate, halogen, guanidinate, triazenide, carboxylate, cyclopentadienyl, and/or aryl.

In a particular embodiment, the method as disclosed herein provides that the one or more metal precursor comprises a metal element chosen from the group including at least one of Ga and W.

In a particular embodiment, the method as disclosed herein provides that the metal element is tungsten (W) and the one or more metal precursor is chosen from the group including at least one of formula (I), formula (II), and formula (III)

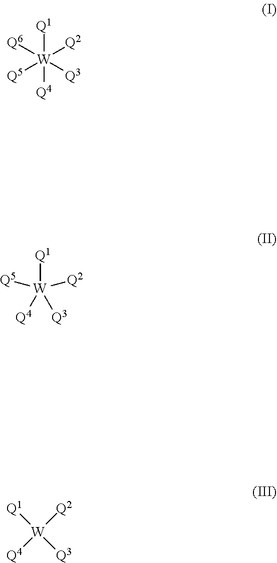

wherein Q¹, Q², Q³, Q⁴, Q⁵, Q⁶ are each independently chosen from the group consisting of CO, F, Cl, Br, I, alkyl, alkenyl, N(R¹)₂, alkoxy, cycloalkoxy, cycloalkyl, aryl, arylalkyl, alkylaryl, cyclopentadienyl, alkyl-substituted cyclopentadienyl, and heteroalkyl; wherein each R¹ is independently chosen from the group consisting of hydrogen, alkyl, cycloalkyl, aryl, arylalkyl, alkylaryl, and heteroalkyl.

In some embodiments, the method as disclosed herein provides that Q¹, Q², Q³, Q⁴, Q⁵, Q⁶ are each independently chosen from the group consisting of CO, F, Cl, Br, I, C₁₋₈alkyl, C₂₋₈alkenyl, N(R¹)₂, C₁₋₈alkoxy, C₃₋₈cycloalkoxy, C₃₋₈cycloalkyl, C₆₋₁₀aryl, C₆₋₁₀arylC₁₋₈alkyl, C₁₋₈alkylC₆₋₁₀aryl, cyclopentadienyl, C₁₋₈alkyl-substituted cyclopentadienyl, and heteroC₁₋₈alkyl; wherein each R¹ is independently chosen from the group consisting of hydrogen, C₁₋₈alkyl, C₃₋₈cycloalkyl, C₆₋₁₀aryl, C₆₋₁₀arylC₁₋₈alkyl, C₁₋₈alkylC₆₋₁₀aryl, and heteroC₁₋₈alkyl.

In some embodiments, the method as disclosed herein provides that Q¹, Q², Q³, Q⁴, Q⁵, Q⁶ are each independently chosen from the group consisting of CO, F, Cl, Br, I, C₁₋₄alkyl, C₂₋₄alkenyl, N(R¹)₂, C₁₋₄alkoxy, C₃₋₈cycloalkoxy, C₃₋₈cycloalkyl, C₆₋₁₀aryl, C₆₋₁₀arylC₁₋₄alkyl, C₁₋₄alkylC₆₋₁₀aryl, cyclopentadienyl, C₁₋₄alkyl-substituted cyclopentadienyl, and heteroC₁₋₄alkyl; wherein each R¹ is independently chosen from the group consisting of hydrogen, C₁₋₄alkyl, C₃₋₈cycloalkyl, C₆₋₁₀aryl, C₆₋₁₀arylC₁₋₄alkyl, C₁₋₄alkylC₆-10aryl, and heteroC₁₋₄alkyl.

In a particular embodiment, the method as disclosed herein provides that the metal element is tungsten (W) and the one or more metal precursor is chosen from the group consisting of WF₆, WCl₆, WBr₆, WI₆, W(CO)₆, WF₂(CO)₄, WCl₂(CO)₄, WBr₂(CO)₄, W(Me)₆, W(Et)₆, W(Pr)₆, W(Bu)₆, W(tBu)₆, W(NME₂)₆, W(NtBu)₂(NMe₂)₄, W(NEt₂)₆, W(acac)₂(CO)₄, W(acac)₁(CO)₅, W(acac)₃(CO)₃, W(Pyr)₆, W(benzene)(CO)₅, W(toluene)(CO)₅, W(cyclopentadienyl)(CO)₅, W(naphthalene)(CO)₅, WF₅, WCl₅, WBr₅, WI₅, W(CO)₅, WF₂(CO)₃, WCl₂(CO)₃, WBr₂(CO)₃, W(Me)₅, W(Et)₅, W(Pr)₅, W(Bu)₅, W(tBu)₅, W(NME₂)₅, W(NtBu)₂(NMe₂)₃, W(NEt₂)₅, W(acac)₂(CO)₃, W(acac)₁(CO)₄, W(acac)₃(CO)₂, W(Pyr)₅, W(benzene)(CO)₄, W(toluene)(CO)₄, W(cyclopentadienyl)(CO)₄, W(naphthalene)(CO)₄, WF₄, WCl₄, WBr₄, WI₄, W(CO)₄, WF₂(CO)₂, WCl₂(CO)₂, WBr₂(CO)₂, W(Me)₄, W(Et)₄, W(Pr)₄, W(Bu)₄, W(tBu)₄, W(NME₂)₄, W(NtBu)₂(NMe₂)₂, W(NEt₂)₄, W(acac)₂(CO)₂, W(acac)₁(CO)₃, W(acac)₃(CO)₁, W(Pyr)₄, W(benzene)(CO)₃, W(toluene)(CO)₃, W(cyclopentadienyl)(CO)₃, and W(naphthalene)(CO)₃.

In a particular embodiment, the method as disclosed herein provides that the metal element is gallium (Ga) and the one or more metal precursor is chosen from the group of formula (IV)

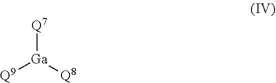

wherein Q⁷, Q⁸, Q⁹ are each independently chosen from the group consisting of F, Cl, Br, I, alkyl, alkenyl, N(R²)₂, alkoxy, cycloalkoxy, cycloalkyl, aryl, arylalkyl, alkylaryl, R³NC(R⁴)NR⁵, R⁶NC[N(R⁷)₂]NR⁸, R⁹N₃R¹⁰, cyclopentadienyl, alkyl-substituted cyclopentadienyl, and heteroalkyl; wherein each R², R³, R⁴, R⁵, R⁶, R⁷, R⁸, R⁹, R¹⁰ is independently chosen from the group consisting of hydrogen, alkyl, cycloalkyl, aryl, arylalkyl, alkylaryl, and heteroalkyl.

In some embodiments, the method as disclosed herein provides that Q⁷, Q⁸, Q⁹ are each independently chosen from the group consisting of F, Cl, Br, I, C₁₋₈alkyl, C₂₋₈alkenyl, N(R²)₂, C₁₋₈alkoxy, C₃₋₈cycloalkoxy, C₃₋₈cycloalkyl, C₆₋₁₀aryl, C₆₋₁₀arylC₁₋₈alkyl, C₁₋₈alkylC₆₋₁₀aryl, R³NC(R⁴)NR⁵, R⁶NC[N(R⁷)₂]NR⁸, R⁹N₃R¹⁰, cyclopentadienyl, C₁₋₈alkyl-substituted cyclopentadienyl, and heteroC₁₋₈alkyl; wherein each R², R³, R⁴, R⁵, R⁶, R⁷, R⁸, R₉, R¹⁰ is independently chosen from the group consisting of hydrogen, C₁₋₈alkyl, C₃₋₈cycloalkyl, C₆₋₁₀aryl, C₆₋₁₀arylC₁₋₈alkyl, C₁₋₈alkylC₆₋₁₀aryl, and heteroC₁₋₈alkyl.

In some embodiments, the method as disclosed herein provides that Q⁷, Q⁸, Q⁹ are each independently chosen from the group consisting of F, Cl, Br, I, C₁₋₄alkyl, C₂₋₄alkenyl, N(R²)₂, C₁₋₄alkoxy, C₃₋₈cycloalkoxy, C₃₋₈cycloalkyl, C₆₋₁₀aryl, C₆₋₁₀arylC₁₋₄alkyl, C₁₋₄alkylC₆₋₁₀aryl, R³NC(R⁴)NR⁵, R⁶NC[N(R⁷)₂]NR⁸, R⁹N₃R¹⁰ and cyclopentadienyl, C₁₋₄alkyl-substituted cyclopentadienyl, heteroC₁₋₄alkyl; wherein each R², R³, R⁴, R⁵, R⁶, R⁷, R⁸, R⁹, R¹⁰ is independently chosen from the group consisting of hydrogen, C₁₋₄alkyl, C₃₋₈cycloalkyl, C₆₋₁₀aryl, C₆₋₁₀arylC₁₋₄alkyl, C₁₋₄alkylC₆₋₁₀aryl, and heteroC₁₋₄alkyl.

In a particular embodiment, the method as disclosed herein provides that the metal element is gallium (Ga) and the one or more metal precursor is chosen from the group consisting of GaF₃, GaCl₃, GaBr₃, GaI₃, Ga(Me)₃, Ga(Et)₃, Ga(Pr)₃, Ga(Bu)₃, Ga(tBu)₃, Ga(NMe₂)₃, Ga(NtBu)₂(NMe₂)₁, Ga(NtBu)₁(NMe₂)₂, Ga(NEt₂)₃, Ga(Pyr)₃, Ga(guanidinate)₃, and Ga(triazenide)₃.

In a particular embodiment, the method as disclosed herein provides that the nitrogen reactant is chosen from the group consisting of N(R¹¹)₃, and (R¹²)NN(R¹³); wherein each R¹¹, R¹², R¹³ is independently chosen from the group consisting of hydrogen, alkyl, alkenyl, cycloalkyl, and Si(R¹⁴)₃; wherein R¹⁴ is chosen from the group consisting of alkyl, alkenyl, alkoxy and Si(R¹⁵)₃; and wherein R¹⁵ is chosen from the group consisting of alkyl, alkenyl, and alkoxy.

In some embodiments, the method as disclosed herein provides that each R¹¹, R¹², R¹³ is independently chosen from the group consisting of hydrogen, C₁₋₈alkyl, C₂₋₈alkenyl, cycloC₃₋₈alkyl, and Si(R¹⁴)₃, wherein R¹⁴ is chosen from the group consisting of C₁₋₈alkyl, C₂₋₈alkenyl, C₁₋₈alkoxy, and Si(R¹⁵)₃; and wherein R¹⁵ is chosen from the group consisting of C₁₋₈alkyl, C₂₋₄alkenyl, and C₁₋₈alkoxy.

In some embodiments, the method as disclosed herein provides that each R¹¹, R¹², R¹³ is independently chosen from the group consisting of hydrogen, C₁₋₄alkyl, C₂₋₄alkenyl, cycloC₃₋₈alkyl, and Si(R¹⁴)₃, wherein R¹⁴ is chosen from the group consisting of C₁₋₄alkyl, C₂₋₄alkenyl, C₁₋₄alkoxy, and Si(R¹⁵)₃; and wherein R¹⁵ is chosen from the group consisting of C₁₋₄alkyl, C₂₋₄alkenyl, and C₁₋₄alkoxy.

In a particular embodiment, the method as disclosed herein provides that the nitrogen reactant is selected from the group including at least one of NH₃, diazene (N₂H₂), hydrazine (N₂H₄), methylhydrazine (N₂MeH₃), ethylhydrazine (N₂EtH₃), propylhydrazine (N₂PrH₃), butylhydrazine (N₂BuH₃), tert-butylhydrazine (N₂tBuH₃), 1,1-dimethylhydrazine (N₂Me₂H₂), 1,1-diethylhydrazine (N₂Et₂H₂), 1,1-dipropylhydrazine (N₂Pr₂H₂), 1,1-dibutylhydrazine (N₂Bu₂H₂), trimethylsilylhydrazine (N₂[Si(Me)₃]H₂), and tris(trimethylsilyl)silylhydrazine (N₂[Si(Si(Me)₃)₃]H₂).

In a particular embodiment, the method as disclosed herein provides that the oxygen reactant is chosen from the group including at least one of H₂O, D₂O, H₂O₂, O₃, O₂, N₂O, NO, N₂O₅, SO₂, oxygen-containing plasma, and oxygen radicals.

In a particular embodiment, the method as disclosed herein provides that the metal and nitrogen containing film comprises at least one of Galium Nitride (GaN) and Tungsten Nitride (WN).

In a particular embodiment, the method as disclosed herein provides that the metal, oxygen, and nitrogen containing film comprises at least one of Gallium Oxynitride (GaON) and Tungsten Oxynitride (WON).

In a particular embodiment, the method as disclosed herein comprises from at least 1 cycle to at most 1000 cycles, preferably from at least 2 cycles to at most 100 cycles.

In a particular embodiment, the method as disclosed herein provides that one cycle comprises one or more metal precursor pulse and one or more nitrogen reactant pulse.

In a particular embodiment, the method as disclosed herein provides that each pulse is followed by a purge with an inert gas chosen from at least one of N₂ and a noble gas.

In a particular embodiment, the method as disclosed herein provides that the dipole layer has an average thickness of 1 nm or less.

In a particular embodiment, the method as disclosed herein provides that the one or more cycle, comprising the steps of contacting one or more metal precursor with at least a part of the substrate and providing the nitrogen reactant into the reaction chamber is fully oxygen free.

In a particular embodiment, the method as disclosed herein provides that a ligand compound is contacted with at least a part of the substrate together with the one or more metal precursor.

In a particular embodiment, the method as disclosed herein provides that the ligand compound is chosen from the group including at least one of XN(R¹⁶)₂, and beta-diketone; wherein X is hydrogen or an alkali metal chosen from the group consisting of Li, Na, K, and Rb; and wherein R¹⁶ is chosen from the group consisting of alkyl, and Si(R¹⁷)₃; and wherein R¹⁷ is chosen from the group consisting of alkyl, alkenyl, and alkoxy.

In some embodiments, the method as disclosed herein provides that R¹⁶ is chosen from the group consisting of C₁₋₈alkyl, and Si(R¹⁷)₃; and wherein R¹⁷ is chosen from the group consisting of C₁₋₈alkyl, C₂₋₈alkenyl, and C₁₋₈alkoxy.

In some embodiments, the method as disclosed herein provides that R¹⁶ is chosen from the group consisting of C₁₋₄alkyl, and Si(R¹⁷)₃; and wherein R¹⁷ is chosen from the group consisting of C₁₋₄alkyl, C₂₋₄alkenyl, and C₁₋₄alkoxy.

In a particular embodiment, the method as disclosed herein provides that the ligand compound is dialkyldisilazane, or a salt thereof.

In a particular embodiment, the method as disclosed herein provides that the ligand compound is chosen from the group consisting of acetylacetonate, 2,2,6,6-tetramethylheptane-3,5-dionate, and 1,1,1,5,5,5-hexafluoropentane-2,4-dionate.

In a particular embodiment, the method as disclosed herein provides that the one or more metal precursor is a metal bis (arene) precursor, wherein the arene ligand is an Eta6-benzene or an Eta6-benzene derivative.

In a particular embodiment, the method as disclosed herein provides that the cycle further comprises a step of providing an organic molecule reactant into the reaction chamber, which comprises at least one halogen group, prior to or subsequent to providing the nitrogen reactant.

In a particular embodiment, the method as disclosed herein provides that the organic molecule reactant is chosen from the group of formula (V)

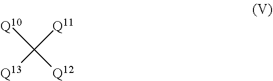

wherein Q¹⁰, Q¹¹, Q¹², Q¹³ are each independently chosen from the group consisting of hydrogen, halogen, alkyl, alkenyl, cycloalkyl, aryl, alkylaryl, arylalkyl, alkoxy, and heteroalkyl; and wherein at least one of Q¹⁰, Q¹¹, Q¹², Q¹³ is halogen.

In some embodiments, the method as disclosed herein provides that Q¹⁰, Q¹¹, Q¹², Q¹³ are each independently chosen from the group consisting of hydrogen, halogen, C₁₋₈alkyl, C₁₋₈alkenyl, C₃₋₈cycloalkyl, C₆₋₁₀aryl, C₁₋₈alkylC₆₋₁₀aryl, C₆₋₁₀arylC₁₋₈alkyl, C₁₋₈alkoxy, and heteroC₁₋₈alkyl; and wherein at least one of Q¹⁰, Q¹¹, Q¹², Q¹³ is halogen.

In some embodiments, the method as disclosed herein provides that Q¹⁰, Q¹¹, Q¹², Q¹³ are each independently chosen from the group consisting of hydrogen, halogen, C₁₋₄alkyl, C₁₋₄alkenyl, C₃₋₈cycloalkyl, C₆₋₁₀aryl, C₁₋₄alkylC₆₋₁₀aryl, C₆₋₁₀arylC₁₋₄alkyl, C₁₋₄alkoxy, and heteroC₁₋₄alkyl; and wherein at least one of Q¹⁰, Q¹¹, Q¹², Q¹³ is F, Cl, Br, or I.

In a particular embodiment, the method as disclosed herein provides that the organic molecule reactant is chosen from the group consisting of chloromethane (CH₃Cl), bromomethane (CH₃Br), iodomethane (CH₃I), dichloromethane (CH₂Cl₂), dibromomethane (CH₂Br₂), diiodomethane (CH₂I₂), trichloromethane (CHCl₃), tribromomethane (CHBr₃), triiodomethane (CHI₃), chloroethane (C₂H₅Cl), bromoethane (C₂H₅Br), iodoethane (C₂H₅I), 1,2-dichloroethane (C₂H₄Cl₂), 1,2-dibromoethane (C₂H₄Br₂), 1,2-diiodoethane (C₂H₄I₂), chloropropane (C₃H₇Cl), bromopropane (C₃H₇Br), iodopropane (C₃H₇I), 1,3-dichloropropane (C₃H₆Cl₂), 1,3-dibromopropane (C₃H₆Br₂), 1,3-diiodopropane (C₃H₆I₂), chlorobutane (C₄H₉Cl), bromobutane (C₄H₉Br), iodobutane (C₄H₉I), 1,4-dichlorobutane (C₄H₈Cl₂), 1,4-dibromobutane (C₄H₈Br₂), 1,4-diiodobutane (C₄H₈I₂), benzyl chloride (C₇H₇Cl), benzyl bromide (C₇H₇Br), benzyl iodide (C₇H₇I), chlorobenzene (C₆H₅Cl), bromobenzene (C₆H₅Br), and iodobenzene (C₆H₅I).

In a particular embodiment, the method as disclosed herein provides that the substrate comprises silicon or silicon oxide.

In a particular embodiment, the method as disclosed herein further comprises the step of forming a high-K dielectric on the dipole layer.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 describes an exemplary embodiment of a method for forming a semiconductor structure comprising a dipole layer. The method starts (111) after a substrate has been provided to a reaction chamber. The cyclical deposition process comprises contacting one or more metal precursor with at least a part of the substrate in a metal precursor pulse (112). Optionally, the reaction chamber is purged (113) after the metal precursor pulse (112). Then, a nitrogen reactant is provided to the reaction chamber in a nitrogen reactant pulse (114). Optionally, the reaction chamber can be purged (115) after the nitrogen reactant pulse. The metal precursor pulse (112), the nitrogen reactant pulse (114), and the optional purges (113,115) can be repeated (116) any number of times to obtain a metal nitride containing film having a desired thickness. When a metal nitride containing layer having a desired thickness has been deposited, the method ends (117). Once the method has ended, the substrate can, for example, be subjected to additional processes to form a device structure and/or device.

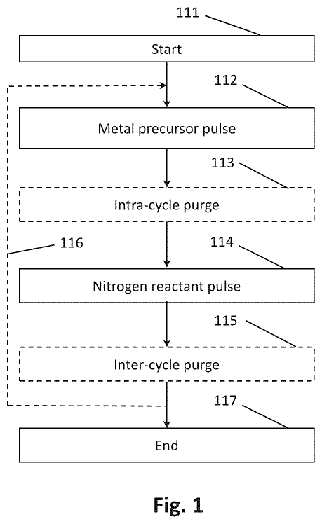

FIG. 2 describes an exemplary embodiment of a method for forming a semiconductor structure comprising a dipole layer. The method starts (211) after a substrate has been provided to a reaction chamber. The cyclical deposition process comprises providing a nitrogen reactant to the reaction chamber in a nitrogen reactant pulse (212). Optionally, the reaction chamber is purged (213) after the nitrogen reactant pulse (212). Then, one or more metal precursor is contacted with at least a part of the substrate in a metal precursor pulse (214). Optionally, the reaction chamber can be purged (215) after the metal precursor pulse. The nitrogen reactant pulse (212), the metal precursor pulse (214), and the optional purges (213,215) can be repeated (216) any number of times to obtain a metal nitride containing film having a desired thickness. When a metal nitride containing layer having a desired thickness has been deposited, the method ends (217). Once the method has ended, the substrate can, for example, be subjected to additional processes to form a device structure and/or device.

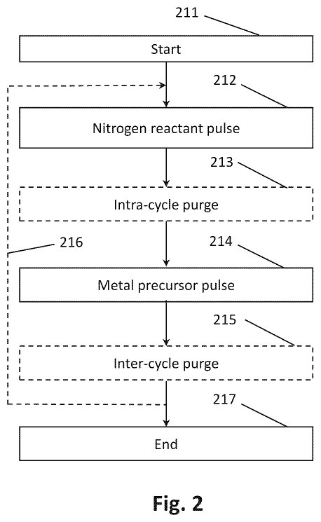

FIG. 3 illustrates another exemplary embodiment of the disclosure. The method starts (311) after a substrate has been provided to a reaction chamber. The cyclical deposition process comprises contacting one or more metal precursor with at least a part of the substrate in a metal precursor pulse (312). Optionally, the reaction chamber is purged (313) after the metal precursor pulse (312). Then, a nitrogen reactant is provided to the reaction chamber in a nitrogen reactant pulse (314). Optionally, the reaction chamber can be purged (315) after the nitrogen reactant pulse. Then, an oxygen reactant is provided to the reaction chamber in an oxygen reactant pulse (316). Optionally, the reaction chamber can be purged (317) after the oxygen reactant pulse. The metal precursor pulse (312), the nitrogen reactant pulse (314), the oxygen reactant pulse (316), and the optional purges (313,315,317) can be repeated (318) any number of times to obtain a metal oxynitride containing film having a desired thickness. When a metal oxynitride containing layer having a desired thickness has been deposited, the method ends (319). Once the method has ended, the substrate can, for example, be subjected to additional processes to form a device structure and/or device.

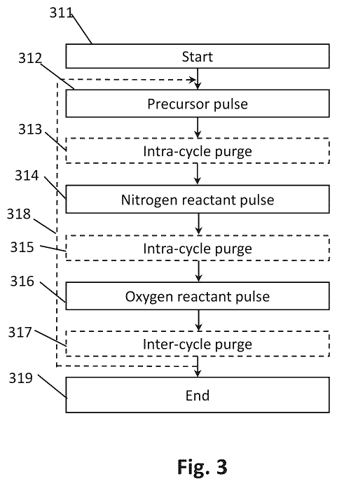

FIG. 4 illustrates another exemplary embodiment of the disclosure. The method starts (411) after a substrate has been provided to a reaction chamber. The cyclical deposition process comprises providing a nitrogen reactant to the reaction chamber in a nitrogen reactant pulse (412). Optionally, the reaction chamber is purged (413) after the nitrogen reactant pulse (412). Then, the one or more metal precursor is contacted with at least a part of the substrate in a metal precursor pulse (414). Optionally, the reaction chamber can be purged (415) after the metal precursor pulse. Then, an oxygen reactant is provided to the reaction chamber in an oxygen reactant pulse (416). Optionally, the reaction chamber can be purged (417) after the oxygen reactant pulse. The nitrogen reactant pulse (412), the metal precursor pulse (414), the oxygen reactant pulse (416), and the optional purges (413,415,417) can be repeated (418) any number of times to obtain a metal oxynitride containing film having a desired thickness. When a metal oxynitride containing layer having a desired thickness has been deposited, the method ends (419). Once the method has ended, the substrate can, for example, be subjected to additional processes to form a device structure and/or device.

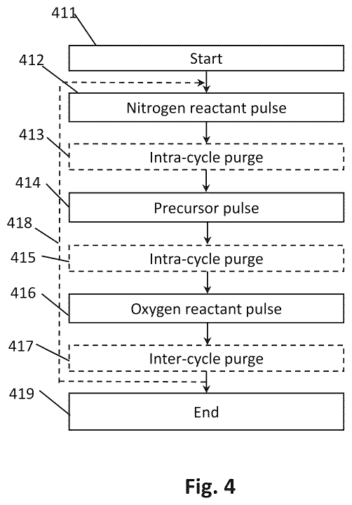

As illustrated in FIG. 1 to FIG. 4, each metal precursor pulse, nitrogen reactant pulse and/or oxygen reactant pulse has a sequential order. However, unless noted otherwise, the herein disclosed method is not limited to the described order of pulses. For instance, the order of each pulse during each cycle may be changed according to the application.

FIG. 5 illustrates a system (500) in accordance with yet additional exemplary embodiments of the disclosure. The system (500) can be used to perform a method as described herein and/or form a structure or device portion as described herein.

In the illustrated example, the system (500) includes one or more reaction chambers (502), a metal precursor gas source (504), a nitrogen reactant gas source (506), a purge gas source (508), an exhaust (510), and a controller (512). The reaction chamber (502) can include any suitable reaction chamber, such as an ALD or CVD reaction chamber. Optionally, the system (500) comprises further gas sources such as an oxygen reactant containing gas source (505).

The metal precursor gas source (504) can include a vessel and one or more precursors as described herein-alone or mixed with one or more carrier (e.g., inert) gases. The nitrogen reactant gas source (506) can include a vessel and one or more nitrogen reactants as described herein-alone or mixed with one or more carrier gases. The purge gas source (508) can include one or more inert gases such as N₂ or a noble gas, as described herein. The system (500) can include any suitable number of gas sources. The gas sources (504)-(508) can be coupled to reaction chamber (502) via lines (514)-(518), which can each include flow controllers, valves, heaters, and the like. The exhaust (510) can include one or more vacuum pumps.

The controller (512) includes electronic circuitry and software to selectively operate valves, manifolds, heaters, pumps and other components included in the system (500). Such circuitry and components operate to introduce precursors, reactants, and purge gases from the respective sources (504)-(508). The controller (512) can control timing of gas pulse sequences, temperature of the substrate and/or reaction chamber, pressure within the reaction chamber, and various other operations to provide proper operation of the system (500). The controller (512) can include control software to electrically or pneumatically control valves to control flow of precursors, reactants (i.e. nitrogen reactants and/or oxygen reactants) and purge gases into and out of the reaction chamber (502). The controller (512) can include modules such as a software or hardware component, e.g., a FPGA or ASIC, which performs certain tasks. A module can advantageously be configured to reside on the addressable storage medium of the control system and be configured to execute one or more processes.

Other configurations of the system (500) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (502). Further, as a schematic representation of a system, many components have been omitted for simplicity of illustration, and such components may include, for example, various valves, manifolds, purifiers, heaters, containers, vents, and/or bypasses.

During operation of the reactor system (500), substrates, such as semiconductor wafers (not illustrated), are transferred from, e.g., a substrate handling system to reaction chamber (502). Once substrate(s) are transferred to the reaction chamber (502), one or more gases from the gas sources (504)-(508), such as precursors, reactants, carrier gases, and/or purge gases, are introduced into reaction chamber (502).

FIG. 6 shows a graphic representation of the chemical resistance to TiCl₄ and NH₃ etching of a film deposited on a substrate according to the method described herein, wherein the film comprises gallium and nitrogen (e.g. GaN).

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure disclosed should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” the recited members, elements or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

The term “halo” or “halogen” as a group or part of a group is generic for fluoro (F), chloro (CI), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₂₀alkyl”, as a group or part of a group, refers to a hydrocarbyl group of formula —CₙH₂ₙ₊₁ wherein n is a number ranging from 1 to 20. Thus, for example, “C₁₋₈alkyl” includes all linear or branched alkyl groups with between 1 and 8 carbon atoms, and thus includes methyl, ethyl, n-propyl, i-propyl, butyl and its isomers (e.g. n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e. “alkylene”, this is intended to mean the alkyl group as defined herein having two single bonds as points of attachment to other groups. As used herein, the term “alkylene” also referred as “alkanediyl”, by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), 1-methyl-ethylene (—CH(CH₃)—CH₂—), n-propylene (—CH₂—CH₂—CH₂—), 2-methylpropylene (—CH₂—CH(CH₃)—CH₂—), 3-methylpropylene (—CH₂—CH₂—CH(CH₃)—), n-butylene (—CH₂—CH₂—CH₂—CH₂—), 2-methylbutylene (—CH₂—CH(CH₃)—CH₂—CH₂—), 4-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C₃₋₂₀alkenyl groups are ethenyl, 2-propenyl, 2-butenyl, 3-butenyl, 2-pentenyl and its isomers, 2-hexenyl and its isomers, 2,4-pentadienyl, and the like.

The term “cycloalkyl”, as a group or part of a group, refers to a cyclic alkyl group, that is a monovalent, saturated, hydrocarbyl group having 1 or more cyclic structure, and comprising from 3 to 20 carbon atoms, more preferably from 3 to 10 carbon atoms, more preferably from 3 to 8 carbon atoms; more preferably from 3 to 6 carbon atoms. Cycloalkyl includes all saturated hydrocarbon groups containing 1 or more rings, including monocyclic, bicyclic groups or tricyclic. The further rings of multi-ring cycloalkyls may be either fused, bridged and/or joined through one or more spiro atoms. When a subscript is used herein following a carbon atom, the subscript refers to the number of carbon atoms that the named group may contain. For example, the term “C₃₋₂₀cycloalkyl”, a cyclic alkyl group comprising from 3 to 20 carbon atoms. For example, the term “C₃₋₁₀cycloalkyl”, a cyclic alkyl group comprising from 3 to 10 carbon atoms. For example, the term “C₃₋₈cycloalkyl”, a cyclic alkyl group comprising from 3 to 8 carbon atoms. For example, the term “C₃₋₆cycloalkyl”, a cyclic alkyl group comprising from 3 to 6 carbon atoms. Examples of C₃₋₁₂cycloalkyl groups include but are not limited to adamantly, cyclopropyl, cyclobutyl, cyclopentyl, cyclohexyl, cycloheptyl, cyclooctyl, bicycle[2.2.1]heptan-2yl, (1S,4R)-norbornan-2-yl, (1R,4R)-norbornan-2-yl, (1S,4S)-norbornan-2-yl, (1R,4S)-norbornan-2-yl.

When the suffix “ene” is used in conjunction with a cycloalkyl group, i.e. cycloalkylene, this is intended to mean the cycloalkyl group as defined herein having two single bonds as points of attachment to other groups. Non-limiting examples of “cycloalkylene” include 1,2-cyclopropylene, 1,1-cyclopropylene, 1,1-cyclobutylene, 1,2-cyclobutylene, 1,3-cyclopentylene, 1,1-cyclopentylene, and 1,4-cyclohexylene.

Where an alkylene or cycloalkylene group is present, connectivity to the molecular structure of which it forms part may be through a common carbon atom or different carbon atom. To illustrate this applying the asterisk nomenclature of this disclosure, a C₃alkylene group may be for example *—CH₂CH₂CH₂—*, *—CH(—CH₂CH₃)—* or *—CH₂CH(—CH₃)—*. Likewise, a C₃cycloalkylene group may be

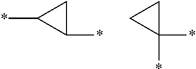

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C₆₋₂₀aryl, preferably C₆₋₁₀aryl, more preferably C₆₋₈aryl. Non-limiting examples of aryl comprise phenyl, biphenylyl, biphenylenyl, or 1- or 2-naphthanelyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2 or 3 substituent(s), or 1 to 2 substituent(s)), at any available point of attachment.

The term “alkoxy” or “alkyloxy”, as a group or part of a group, refers to a group having the formula —OR^{b} wherein R^{b} is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

The term “cycloalkoxy”, as a group or part of a group, refers to a group having the formula —OR^{c} wherein R^{c} is cycloalkyl as defined herein above.

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C₆₋₂₀aryl, preferably C₆₋₁₀aryl, more preferably C₆₋₈aryl. Non-limiting examples of aryl comprise phenyl, biphenylyl, biphenylenyl, or 1- or 2-naphthanelyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2 or 3 substituent(s), or 1 to 2 substituent(s)), at any available point of attachment.

The term “arylalkyl”, as a group or part of a group, means an alkyl as defined herein, wherein at least one hydrogen atom is replaced by at least one aryl as defined herein. Non-limiting examples of arylalkyl group include benzyl, phenethyl, dibenzylmethyl, methylphenylmethyl, 3-(2-naphthyl)-butyl, and the like.

The term “alkylaryl” as a group or part of a group, means an aryl as defined herein wherein at least one hydrogen atom is replaced by at least one alkyl as defined herein. Non-limiting example of alkylaryl group include p-CH₃—R^{d}—, wherein R^{d} is aryl as defined herein above.

The term “heteroalkyl” as a group or part of a group, refers to an acyclic alkyl wherein one or more carbon atoms are replaced by at least one heteroatom selected from the group comprising O, Si, S, B, and P, with the proviso that the chain may not contain two adjacent heteroatoms. This means that one or more —CH₃ of the acyclic alkyl can be replaced by —OH for example and/or that one or more —CR₂— of the acyclic alkyl can be replaced by O, Si, S, B, and P.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, particularly a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

In this disclosure, the following abbreviations of chemical structures are used: Cp stands for cyclopentadienyl, Me stands for methyl; Et stands for ethyl; nPr stands for n-propyl; nBu stands for n-butyl; tBu stands for t-butyl; acac stands for acetylacetonate.

In general, the technology disclosed herein relates to the field of semiconductor devices, and more specifically to a method for forming a semiconductor structure comprising a dipole layer used in the production of several electronic components such as microprocessors, integrated circuit chips, and memory chips. An important step of the semiconductor formation referred to herein can comprise the formation of a film comprising a metal and nitrogen, e.g. a metal nitride film, or layer on an underlying insulating material, such as a high-k dielectric (or gate dielectric) or silicon oxide (or gate oxide). Advantageously, the current inventors have found that the herein disclosed method allows to remove any oxygen or carbon contamination during deposition of the film comprising a metal and nitrogen, resulting in a stable nitrogen-rich layer with a lower thickness. To elaborate, one of the challenges in semiconductor formation, and in particular field-effect transistors, is to lower the equivalent oxide thickness (EOT) of the gate dielectric or gate oxide and avoid leakage current to the gate terminal. In contrast to the state of the art, the current disclosure allows to lower the EOT, while achieving a high capacitance and improved electrical performance of the semiconductor device.

As set forth in more detail below, various embodiments of the present disclosure relate to a method for forming a semiconductor structure comprising a dipole layer, the method comprising the steps of:
a) providing a substrate to a reaction chamber;
b) executing one or more cycles, a cycle comprising
   i. contacting one or more metal precursor with at least a part of the substrate by introducing the one or more metal precursor in the reaction chamber; and
   ii. providing a nitrogen reactant into the reaction chamber, thereby forming a metal and nitrogen containing film on at least part of the substrate.

As used herein, the terms “semiconductor structure” or “semiconductor device” refer to an electronic component that relies on the electronic properties of a semiconductor material for its function. The electrical conductivity of a semiconductor falls between that of a conductor (e.g. copper) and an insulator (e.g. soda-lime silica glass). The herein disclosed method can be used to, for example, form complementary metal-oxide-semiconductor (CMOS) devices, or portions of such devices. However, unless noted otherwise, the disclosure is not necessarily limited to such examples.

As used herein, the term “dipole layer” in a semiconductor structure refers to a region where a net dipole moment is established at or near the surface or interface of the semiconductor material. It is created by introducing (e.g. depositing) a different material, typically a dielectric, onto the surface or interface. A dielectric is an electrical insulator that can be polarized by an applied electric field. Additionally or alternatively, the dielectric surface can comprise a high-k dielectric surface (i.e. high dielectric constant compared to silicon oxide). The dipole layer results from a charge redistribution (i.e. polarization), causing positive charges to accumulate on one side and negative charges on the other. The polarizability of a dipole layer has significant effects on the semiconductor structure, such as modifying surface properties, improving carrier lifetime, creating energy barriers, and controlling band alignment. Dipole layers are widely used in semiconductor technology to enhance device performance and enable specific functionalities by manipulating surface and interface properties.

In some embodiments, the method as disclosed herein is used for the formation of semiconductor devices applied as field-effect transistors (FETs). One of the most common FETs in digital circuits is a metal-oxide-semiconductor field-effect transistor (MOSFET). MOSFETs are devices with a source, gate, and drain terminal and are able to control the flow of an electric current by applying a voltage to the gate, which in turn alters the conductivity between the drain and source. Hence, the semiconductor devices can be used to amplify or switch (e.g. on/off) an electrical signal, depending on the applied voltage. The minimum voltage that is needed to create/terminate a conducting path or channel between the drain and source is often referred to as the threshold voltage (Vₜ).

Typically, semiconductors comprise metal oxides and/or oxide contaminants and a relatively thin equivalent oxide thickness (e.g. 1 nm). The herein disclosed method allows to form semiconductor devices that are characterized by a low EOT and a particularly controlled, e.g. higher or lower threshold voltage. Hence, the resulting semiconductors provide transistors, such as MOSFETS, with a lower leakage current and an increased electrical performance. The present method is particularly useful for producing different transistors with different threshold voltage (Vₜ) (e.g. lower and/or higher) to optimize the response rate and power consumption. For instance, the gate voltage at which a conductive channel is produced between the source and drain of an n-MOSFET may be increased. The n-MOSFET may, for example, be comprised in a CMOS-based integrated circuit. Additionally or alternatively, the gate voltage at which a conductive channel is produced between the source and drain of a p-MOSFET may be decreased. The p-MOSFET may, for example, be comprised in a CMOS-based integrated circuit. In other words, the present method may be particularly useful for increasing or decreasing the voltage at which an n-MOSFET switches from an off-state to an on-state, and for decreasing or increasing the voltage at which a p-MOSFET switches from an off-state to an on-state.

In particular, the formation of a film comprising a metal and nitrogen, e.g. a metal nitride film, or layer on a substrate as described herein relates to a cyclical deposition process, such as an atomic layer deposition process or a cyclical chemical vapor deposition process. In some embodiments, the cyclical deposition process comprises one or more cycles. In particular embodiments, the method as disclosed herein comprises at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 1000 cycles, or from at least 2 cycles to at most 100 cycles, or from at least 5 cycles to at most 50 cycles.

A cycle comprises two or more pulses. In some embodiments, at least one pulse involves a self-limiting surface reaction. In some embodiments, all pulses involve a self-limiting surface reaction. In some embodiments, a cycle comprises a metal precursor pulse and a nitrogen reactant (reactant) pulse. In the metal precursor pulse, the one or more metal precursor is provided into the reaction chamber. In the nitrogen reactant pulse, the nitrogen reactant is provided into the reaction chamber. Hence, a thin film is formed on at least a part of the substrate containing metal and nitrogen (e.g. a metal nitride). In some embodiments, the metal precursor pulse precedes the nitrogen reactant pulse. This notwithstanding, and in other embodiments, the nitrogen reactant pulse may precede the metal precursor pulse.

It shall be understood that any two steps and/or pulses can be separated by a purge. Thus, in some embodiments, the step of contacting the one or more metal precursor and the step of providing the nitrogen reactant are separated by a purge. In some embodiments, subsequent cycles are separated by a purge.

In particular embodiments, the method as disclosed herein provides that the one or more cycle, comprising the steps of contacting one or more metal precursor with at least a part of the substrate and providing the nitrogen reactant into the reaction chamber, is quasi free from oxygen, and preferably fully oxygen free. More specifically, the disclosed method provides that the deposition of the metal and nitrogen containing film is free from oxygen contaminants, thus lowering the equivalent oxide thickness (EOT) of the dipole and the amount of deposition defects.

In some embodiments, the substrate may be made from semiconductor materials, including, for example, silicon, silicon germanium, silicon oxide, gallium arsenide, gallium nitride and silicon carbide. In some preferred embodiments, the substrate comprises silicon or silicon oxide. In a particular embodiment, the substrate is made from silicon or silicon oxide.

In particular embodiments, the substrate comprises at least one of an interlayer and a high-k layer, wherein the herein disclosed method further comprises a step of annealing the substrate, thereby forming a dipole layer. The interlayer as referred herein, may be made from semiconductor materials, including, for example, silicon, silicon oxide, and silicate. The interlayer is typically formed between a silicon substrate and a high-k layer. The high-κ layer comprises a high-κ dielectric that has a dielectric constant larger than the dielectric constant of silicon oxide such as higher than about 7. Non-limiting exemplary high-κ dielectrics include hafnium oxide (HfO₂), tantalum oxide (Ta₂O₅), zirconium oxide (ZrO₂), titanium oxide (TiO₂), hafnium silicate (HfSiOₓ), aluminium oxide (Al₂O₃) or lanthanum oxide (La₂O₃), mixtures thereof, and laminates thereof.

In some embodiments, the method as disclosed herein provides that the metal and nitrogen containing film is formed on the interlayer. In some embodiments, the method as disclosed herein provides that he metal and nitrogen containing film is formed on the high-κ layer.

A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet or a flexible material. Continuous substrates may also comprise carriers or sheets upon which non-continuous substrates are mounted.

In particular embodiments, the method as disclosed herein provides that the one or more cycles comprises a step of providing an oxygen reactant into the reaction chamber, thereby forming a metal, oxygen, and nitrogen containing film on at least part of the substrate. In other words, the present disclosure alternatively or additionally provides the intentional introduction of an oxygen reactant during one or more of the cycles of the method as disclosed herein. Hence, the resulting one or more cycle comprises three or more pulses. In some embodiments, the cycle comprises a metal precursor pulse, a nitrogen reactant pulse and an oxygen reactant pulse. Hence, a thin film is formed on at least a part of the substrate containing metal, nitrogen, and oxygen (e.g. a metal oxynitride). In some embodiments, the metal precursor pulse precedes the nitrogen reactant pulse and oxygen reactant pulse. This notwithstanding, and in other embodiments, the nitrogen reactant pulse and oxygen reactant pulse may precede the metal precursor pulse. This notwithstanding, and in other embodiments, the nitrogen reactant pulse may precede the metal precursor pulse and oxygen reactant pulse. The skilled person understands that different orders of pulses may be possible. Advantageously, by controlling the amount of oxygen and/or oxygen contaminants during each deposition cycle, the present disclosure may lower the amount of surface defects during deposition of the dipole layer and control the EOT to have well defined films of a desired thickness without lowering conductivity and/or capacitance. Moreover, the metal, oxygen, and nitrogen containing film provides additional flexibility since the reactive oxide-containing film can be used for subsequent reactions or deposits of material.

In particular embodiments, suitable oxidizing reagents include an oxygen reactant or gas. In preferred embodiments, the oxygen reactant is chosen from the group including at least one of H₂O, D₂O, H₂O₂, O₃, O₂, N₂O, NO, N₂O₅, SO₂, oxygen-containing plasma, and oxygen radicals.

As used herein, the term “deposition” or “cyclic deposition” or “cyclic deposition process” or “cyclical deposition process” refers to a sequential introduction of metal precursors (and/or reactants) into a reaction chamber to deposit a layer or film over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a deposition process as disclosed herein refers to an atomic layer deposition process. Typically, one deposition cycle may form a film or layer of about 0.10 nm. However, the experimental thickness may vary depending on the amount and type of cycles and available reaction sites on the substrate. In preferred embodiments, the method as disclosed herein provides that the dipole layer has an average thickness of 1 nm or less, or 0.75 nm or less, preferably 0.50 nm or less, or 0.4 nm or less, or 0.3 nm or less, preferably 0.25 nm or less, or 0.2 nm or less, more preferably 0.10 nm or less. In some embodiments, the dipole layer is grown at a rate of 0.10 nm or less per alternating pulses of precursor(s)/reactive gas(es), and purge (e.g., inert carrier) gas(es). A layer of lower thickness may be desirable for many electronics applications, including work function and/or threshold voltage adjustment in transistors.

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a (metal) precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more repetitions, e.g. during each deposition step, to remove any excess precursor from the process chamber and/or remove any excess reactant and/or reaction byproducts from the reaction chamber. Note that, as used herein, ALD processes are not necessarily comprised of a sequence of self-limiting surface reactions. Advantageously, the method of the present disclosure allows to form dipole layers that do not require full film closure to work. Hence, allowing faster deposition with a larger error-tolerance compared to what is disclosed in the state of the art.

In some embodiments, the plurality of deposition cycles can comprise a plurality of master cycles. A master cycle can comprise an oxygen reactant pulse and one or more sub-cycles. A sub-cycle comprises a nitrogen reactant pulse followed by a metal precursor pulse. Thus, in some embodiments, the plurality of deposition cycles can be represented by formula i)

$$[ ( nitrogen reactant + metal precursor ) \times sub - cycle + oxygen reactant ] \times master cycle \qquad i )$$

In which “nitrogen reactant” denotes a nitrogen reactant pulse, “metal precursor” denotes a metal precursor pulse, “x sub-cycle” denotes the number of sub-cycles per master cycle, “oxygen reactant” denotes an oxygen reactant pulse, “x master cycle” denotes the number of master cycles, and “+” denotes that one pulse occurs after the other. In such embodiments, an oxygen reactant is only introduced during the oxygen reactant pulse, such that oxygen-related defects are minimalized.

Additionally or alternatively, and in some embodiments, the metal precursor pulse precedes the nitrogen reactant pulse, giving rise to a cyclical deposition process that can be described by formula ii)

$$[ ( metal precursor + nitrogen reactant ) \times sub - cycle + oxygen reactant ] \times master cycle \qquad ii )$$

In some embodiments, a metal precursor pulse can be executed before executing the master cycles, as indicated by formula iii)

$$[ metal precursor + [ ( nitrogen reactant + metal precursor ) \times sub - cycle + oxygen reactant ] \times master cycle \qquad iii )$$

In some embodiments, the method comprises from at least 2 sub-cycles to at most 5 sub-cycles, or from at least 5 sub-cycles to at most 10 sub-cycles, or from at least 10 sub-cycles to at most 20 sub-cycles, or from at least 20 sub-cycles to at most 50 sub-cycles, or from at least 50 sub-cycles to at most 100 sub-cycles, or from at least 100 sub-cycles to at most 200 sub-cycles, or from at least 200 sub-cycles to at most 500 sub-cycles, or from at least 500 sub-cycles to at most 1000 sub-cycles, or from at least 1000 sub-cycles to at most 2000 sub-cycles.

In particular embodiments, the method as disclosed herein provides that one cycle comprises one or more metal precursor pulse and one or more nitrogen reactant pulse. In some preferred embodiments, each pulse is followed by a purge with an inert gas chosen from at least one of N₂ and a noble gas.

In some embodiments, the metal precursor pulse lasts from at least 0.01s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s. In some embodiments, the nitrogen reactant pulse and/or oxygen reactant pulse lasts from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

In particular embodiments, the method as disclosed herein provides that the one or more metal precursor comprises a metal element chosen from the group consisting of Mg, Ca, Sr, Ba, Al, Ga, In, Sc, Y, La, Ce, Pr, Nd, Pm, Sm, Eu, Gd, Tb, Dy, Ho, Er, Tm, Yb, Lu, Ti, Zr, Hf, V, Nb, Ta, Cr, Mo, Re, Ge, Sb, Zn, and W. The metal element may be in any suitable oxidation state, e.g. in oxidation state +2, in oxidation state +3, in oxidation state +4, in oxidation state +5, or in oxidation state +6. The metal precursor may have a low carbon impurity content e.g. a carbon content of 1.0, or 0.1 atomic percent, or less. The one or more metal precursor may comprise a ligand. The ligand is typically an ion or molecule with a functional group capable of binding to the central metal atom to form a coordination complex. In some embodiments, the method as disclosed herein provides that the ligand is chosen from the group including at least one of amine, alkenyl, carbonyl, alkoxide, beta-diketone, diazadiene, amidinate, halogen, guanidinate, triazenide, carboxylate, cyclopentadienyl, and/or aryl.

In particular embodiments, the method as disclosed herein provides that the one or more metal precursor comprises a metal element chosen from the group including at least one of Ga and W. The inventors surprisingly found that films containing nitrogen, and gallium and/or tungsten can be particularly advantageous for controlling the threshold voltage of semiconductor structures.

In particular embodiments, the method as disclosed herein provides that the metal element is tungsten (W) and the one or more metal precursor is chosen from the group including at least one of formula (I), formula (II), and formula (III) wherein

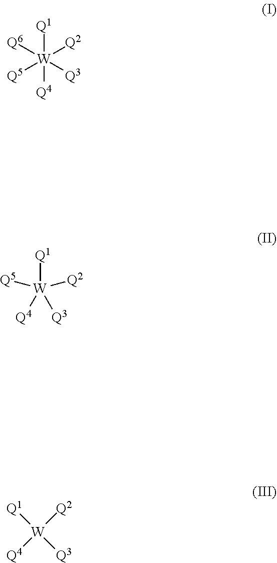

Q¹, Q², Q³, Q⁴, Q⁵, Q⁶ are each independently chosen from the group consisting of CO, F, Cl, Br, I, alkyl, alkenyl, N(R¹)₂, alkoxy, cycloalkoxy, cycloalkyl, aryl, arylalkyl, alkylaryl, cyclopentadienyl, alkyl-substituted cyclopentadienyl, and heteroalkyl; wherein each R¹ is independently chosen from the group consisting of hydrogen, alkyl, cycloalkyl, aryl, arylalkyl, alkylaryl, and heteroalkyl.

In some embodiments, the present disclosure provides that Q¹, Q², Q³, Q⁴, Q⁵, Q⁶ are each independently chosen from the group consisting of CO, F, Cl, Br, I, C₁₋₂₀alkyl, C₂₋₂₀alkenyl, N(R¹)₂, C₁₋₂₀alkoxy, C₃₋₂₀cycloalkoxy, C₃₋₂₀cycloalkyl, C₆₋₂₀aryl, C₆₋₂₀arylC₁₋₂₀alkyl, C₁₋₂₀alkylC₆₋₂₀aryl, cyclopentadienyl, C₁₋₂₀alkyl-substituted cyclopentadienyl, and heteroC₁₋₂₀alkyl; wherein each R¹ is independently chosen from the group consisting of hydrogen, C₁₋₂₀alkyl, C₃₋₂₀cycloalkyl, C₆₋₂₀aryl, C₆₋₂₀arylC₁₋₂₀alkyl, C₁₋₂₀alkylC₆₋₂₀aryl, and heteroC₁₋₂₀alkyl.

In some embodiments, the present disclosure provides that Q¹, Q², Q³, Q⁴, Q⁵, Q⁶ are each independently chosen from the group consisting of CO, F, Cl, Br, I, C₁₋₈alkyl, C₂₋₈alkenyl, N(R¹)₂, C₁₋₈alkoxy, C₃₋₈cycloalkoxy, C₃₋₈cycloalkyl, C₆₋₁₀aryl, C₆₋₁₀arylC₁₋₈alkyl, C₁₋₈alkylC₆₋₁₀aryl, cyclopentadienyl, C₁₋₈alkyl-substituted cyclopentadienyl, and heteroC₁₋₈alkyl; wherein each R¹ is independently chosen from the group consisting of hydrogen, C₁₋₈alkyl, C₃₋₈cycloalkyl, C₆₋₁₀aryl, C₆₋₁₀arylC₁₋₈alkyl, C₁₋₈alkylC₆₋₁₀aryl, and heteroC₁₋₈alkyl.

In some embodiments, the present disclosure provides that Q¹, Q², Q³, Q⁴, Q⁵, Q⁶ are each independently chosen from the group consisting of CO, F, Cl, Br, I, C₁₋₄alkyl, C₂₋₄alkenyl, N(R¹)₂, C₁₋₄alkoxy, C₃₋₈cycloalkoxy, C₃₋₈cycloalkyl, C₆₋₁₀aryl, C₆₋₁₀arylC₁₋₄alkyl, C₁₋₄alkylC₆₋₁₀aryl, cyclopentadienyl, C₁₋₄alkyl-substituted cyclopentadienyl, and heteroC₁₋₄alkyl; wherein each R¹ is independently chosen from the group consisting of hydrogen, C₁₋₄alkyl, C₃₋₈cycloalkyl, C₆₋₁₀aryl, C₆₋₁₀arylC₁₋₄alkyl, C₁₋₄alkylC₆₋₁₀aryl, and heteroC₁₋₄alkyl.

In particular embodiments, the method as disclosed herein provides that the metal element is tungsten (W) and the one or more metal precursor is chosen from the group consisting of WF₆, WCl₆, WBr₆, WI₆, W(CO)₆, WF₂(CO)₄, WCl₂(CO)₄, WBr₂(CO)₄, W(Me)₆, W(Et)₆, W(nPr)₆, W(nBu)₆, W(tBu)₆, W(NME₂)₆, W(NtBu)₂(NMe₂)₄, W(NEt₂)₆, W(acac)₂(CO)₄, W(acac)₁(CO)₅, W(acac)₃(CO)₃, W(Pyr)₆, W(benzene)(CO)₅, W(toluene)(CO)₅, W(cyclopentadienyl)(CO)₅, W(naphthalene)(CO)₅, WF₅, WCl₅, WBr₅, WI₅, W(CO)₅, WF₂(CO)₃, WCl₂(CO)₃, WBr₂(CO)₃, W(Me)₅, W(Et)₅, W(nPr)₅, W(nBu)₅, W(tBu)₅, W(NME₂)₅, W(NtBu)₂(NMe₂)₃, W(NEt₂)₅, W(acac)₂(CO)₃, W(acac)₁(CO)₄, W(acac)₃(CO)₂, W(Pyr)₅, W(benzene)(CO)₄, W(toluene)(CO)₄, W(cyclopentadienyl)(CO)₄, W(naphthalene)(CO)₄, WF₄, WCl₄, WBr₄, WI₄, W(CO)₄, WF₂(CO)₂, WCl₂(CO)₂, WBr₂(CO)₂, W(Me)₄, W(Et)₄, W(nPr)₄, W(nBu)₄, W(tBu)₄, W(NME₂)₄, W(NtBu)₂(NMe₂)₂, W(NEt₂)₄, W(acac)₂(CO)₂, W(acac)₁(CO)₃, W(acac)₃(CO)₁, W(Pyr)₄, W(benzene)(CO)₃, W(toluene)(CO)₃, W(cyclopentadienyl)(CO)₃, and W(naphthalene)(CO)₃.

In particular embodiments, the method as disclosed herein provides that the metal element is gallium (Ga) and the one or more metal precursor is chosen from the group of formula (IV) wherein

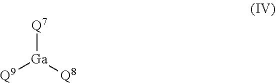

Q⁷, Q⁸, Q⁹ are each independently chosen from the group consisting of F, Cl, Br, I, alkyl, alkenyl, N(R²)₂, alkoxy, cycloalkoxy, cycloalkyl, aryl, arylalkyl, alkylaryl, R³NC(R⁴)NR⁵, R⁶NC[N(R⁷)₂]NR⁸, R⁹N₃R¹⁰ cyclopentadienyl, alkyl-substituted cyclopentadienyl, and heteroalkyl; wherein each R², R³, R⁴, R⁵, R⁶, R⁷, R⁸, R⁹, R¹⁰ is independently chosen from the group consisting of hydrogen, alkyl, cycloalkyl, aryl, arylalkyl, alkylaryl, and heteroalkyl.

In some embodiments, the present disclosure provides that Q⁷, Q⁸, Q⁹ are each independently chosen from the group consisting of F, Cl, Br, I, C₁₋₂₀alkyl, C₂₋₂₀alkenyl, N(R²)₂, C₁₋₂₀alkoxy, C₃₋₂₀cycloalkoxy, C₃₋₂₀cycloalkyl, C₆₋₂₀aryl, C₆₋₂₀arylC₁₋₂₀alkyl, C₁₋₂₀alkylC₆₋₂₀aryl, R³NC(R⁴)NR⁵, R⁶NC[N(R⁷)₂]NR⁸, R⁹N₃R¹⁰ cyclopentadienyl, C₁₋₂₀alkyl-substituted cyclopentadienyl, and heteroC₁₋₂₀alkyl; wherein each R², R³, R⁴, R⁵, R⁶, R⁷, R⁸, R⁹, R¹⁰ is independently chosen from the group consisting of hydrogen, C₁₋₂₀alkyl, C₃₋₂₀cycloalkyl, C₆₋₂₀aryl, C₆₋₂₀arylC₁₋₂₀alkyl, C₁₋₂₀alkylC₆₋₂₀aryl, and heteroC₁₋₂₀alkyl.

In some embodiments, the present disclosure provides that Q⁷, Q⁸, Q⁹ are each independently chosen from the group consisting of F, Cl, Br, I, C₁₋₈alkyl, C₂₋₈alkenyl, N(R²)₂, C₁₋₄alkoxy, C₃₋₈cycloalkoxy, C₃₋₈cycloalkyl, C₆₋₁₀aryl, C₆₋₁₀arylC₁₋₈alkyl, C₁₋₈alkylC₆₋₁₀aryl, R³NC(R⁴)NR⁵, R⁶NC[N(R⁷)₂]NR⁸, R⁹N₃R¹⁰ cyclopentadienyl, C₁₋₈alkyl-substituted cyclopentadienyl, and heteroC₁₋₈alkyl; wherein each R², R³, R⁴, R⁵, R⁶, R⁷, R⁸, R⁹, R¹⁰ is independently chosen from the group consisting of hydrogen, C₁₋₈alkyl, C₃₋₈cycloalkyl, C₆₋₁₀aryl, C₆₋₁₀arylC₁₋₈alkyl, C₁₋₈alkylC₆₋₁₀aryl, and heteroC₁₋₈alkyl.

In some embodiments, the present disclosure provides that Q⁷, Q⁸, Q⁹ are each independently chosen from the group consisting of F, Cl, Br, I, C₁₋₄alkyl, C₂₋₄alkenyl, N(R²)₂, C₁₋₄alkoxy, C₃₋₈cycloalkoxy, C₃₋₈cycloalkyl, C₆₋₁₀aryl, C₆₋₁₀arylC₁₋₄alkyl, C₁₋₄alkylC₆₋₁₀aryl, R³NC(R⁴)NR⁵, R⁶NC[N(R⁷)₂]NR⁸, R⁹N₃R¹⁰ and cyclopentadienyl, C₁₋₄alkyl-substituted cyclopentadienyl, heteroC₁₋₄alkyl; wherein each R², R³, R⁴, R⁵, R⁶, R⁷, R⁸, R⁹, R¹⁰ is independently chosen from the group consisting of hydrogen, C₁₋₄alkyl, C₃₋₈cycloalkyl, C₆₋₁₀aryl, C₆₋₁₀arylC₁₋₄alkyl, C₁₋₄alkylC₆₋₁₀aryl, and heteroC₁₋₄alkyl.

In particular embodiments, the method as disclosed herein provides that the metal element is gallium (Ga) and the one or more metal precursor is chosen from the group consisting of GaF₃, GaCl₃, GaBr₃, GaI₃, Ga(Me)₃, Ga(Et)₃, Ga(nPr)₃, Ga(nBu)₃, Ga(tBu)₃, Ga(NMe₂)₃, Ga(NtBu)₂(NMe₂)₁, Ga(NtBu)₁(NMe₂)₂, Ga(NEt₂)₃, Ga(Pyr)₃, Ga(guanidinate)₃, Ga(triazenide)₃.

In particular embodiments, the method as disclosed herein provides that the nitrogen reactant is chosen from the group consisting of N(R¹¹)₃, and (R¹²)NN(R¹³); wherein each R¹¹, R¹², R¹³ is independently chosen from the group consisting of hydrogen, alkyl, alkenyl, cycloalkyl, and Si(R¹⁴)₃; wherein R¹⁴ is chosen from the group consisting of alkyl, alkenyl, alkoxy and Si(R¹⁵)₃; and wherein R¹⁵ is chosen from the group consisting of alkyl, alkenyl, alkoxy.

In some embodiments, the present disclosure provides that each R¹¹, R¹², R¹³ is independently chosen from the group consisting of hydrogen, C₁₋₂₀alkyl, C₂₋₂₀alkenyl, cycloC₃₋₂₀alkyl, and Si(R¹⁴)₃, wherein R¹⁴ is chosen from the group consisting of C₁₋₂₀alkyl, C₂₋₂₀alkenyl, C₁₋₂₀alkoxy, and Si(R¹⁵)₃; and wherein R¹⁵ is chosen from the group consisting of C₁₋₂₀alkyl, C₂₋₂₀alkenyl, C₁₋₂₀alkoxy.

In some embodiments, the present disclosure provides that each R¹¹, R¹², R¹³ is independently chosen from the group consisting of hydrogen, C₁₋₈alkyl, C₂₋₈alkenyl, cycloC₃₋₈alkyl, and Si(R¹⁴)₃, wherein R¹⁴ is chosen from the group consisting of C₁₋₈alkyl, C₂₋₈alkenyl, C₁₋₈alkoxy, and Si(R¹⁵)₃; and wherein R¹⁵ is chosen from the group consisting of C₁₋₈alkyl, C₂₋₈alkenyl, C₁₋₈alkoxy.

In some embodiments, the present disclosure provides that each R¹¹, R¹², R¹³ is independently chosen from the group consisting of hydrogen, C₁₋₄alkyl, C₂₋₄alkenyl, cycloC₃₋₈alkyl, and Si(R¹⁴)₃, wherein R¹⁴ is chosen from the group consisting of C₁₋₄alkyl, C₂₋₄alkenyl, C₁₋₄alkoxy, and Si(R¹⁵)₃; and wherein R¹⁵ is chosen from the group consisting of C₁₋₄alkyl, C₂₋₄alkenyl, C₁₋₄alkoxy.

In particular embodiments, the method as disclosed herein provides that the one or more metal precursor is a metal bis (arene) precursor, wherein the arene ligand is an Eta6-benzene or an Eta6-benzene derivative.

In particular embodiments, the method as disclosed herein provides that the nitrogen reactant is selected from the group including at least one of NH₃, diazene (N₂H₂), hydrazine (N₂H₄), methylhydrazine (N₂MeH₃), ethylhydrazine (N₂EtH₃), propylhydrazine (N₂nPrH₃), butylhydrazine (N₂nBuH₃), tert-butylhydrazine (N₂tBuH₃), 1,1-dimethylhydrazine (N₂Me₂H₂), 1,1-diethylhydrazine (N₂Et₂H₂), 1,1-dipropylhydrazine (N₂nPr₂H₂), 1,1-dibutylhydrazine (N₂nBu₂H₂), trimethylsilylhydrazine (N₂[Si(Me)₃]H₂), and tris(trimethylsilyl)silylhydrazine (N₂[Si(Si(Me)₃)₃]H₂). Advantageously, the nitrogen reactants disclosed herein are characterized by a low volatility and are thereby easy to vaporize. As such, the method as disclosed herein does not necessarily have to be performed at high temperatures (e.g. close to the decomposition temperature of the disclosed materials).

In some particular embodiments, the method as disclosed herein provides that the metal and nitrogen containing film comprises at least one of Galium Nitride (GaN) and Tungsten Nitride (WN). Advantageously, Galium Nitride (GaN) and Tungsten Nitride (WN) are particularly suitable components for p-type dipole layers. Advantageously, Galium Nitride (GaN) and Tungsten Nitride (WN) are particularly suitable components for n-type dipole layers. Moreover, the inventors found that the films or layers deposited with the method as disclosed herein containing GaN and/or WN are resistant to chemicals, such as acids and bases, oxidation, and heat. Hence, the method as disclosed herein provides semiconductor structures with a high functional density, while overcoming at least some of the drawbacks of the prior art.

In a particular embodiment, the method as disclosed herein provides that the metal, oxygen, and nitrogen containing film comprises at least one of Gallium Oxynitride (GaON) and Tungsten Oxynitride (WON).

It shall be understood that when a metal nitride and/or metal oxynitride containing film or layer is deposited on the substrate, intermixing of those layer's constituent components may occur to some extent. For example, when a gallium oxynitride (GaON) containing layer is deposited on a tungsten nitride (WN) layer, at least one of gallium, nitrogen, or oxygen may be incorporated in the tungsten nitride containing layer, for example by means of diffusion, surface segregation, or another process. For example, when a tungsten oxynitride (WON) containing layer is deposited on a hafnium oxide (HfO₂), hafnium may be incorporated in the tungsten nitride containing layer. In some embodiments, such intermixing can result in the formation of an interlayer containing both components of each layer. Moreover, the extremely thin metal nitride and/or metal oxynitride film may further comprise hydrogen and/or carbon in the resulting deposited films or layers.

It shall be understood that when a metal nitride is abbreviated by means of a chemical formula, that chemical formula can indicate the metal nitride in the stoichiometry given, or in any other stoichiometry, including non-stoichiometric forms, depending, for example, on the oxidation state of the metal in question. For example, when tungsten nitride is abbreviated as “WN”, the term WN can mean a tungsten and nitrogen containing material in which tungsten and nitrogen are present in a 1:1 ratio, or in any other suitable ratio, such as 0.8:2, 1:2, 1.5:2, 0.8:1, 0.9:1, 0.95:1, 1:1.05, 1:1.1, 1.2, 1.5, 2:1, 2.5:1, etc. Similar considerations apply to a metal oxynitride as disclosed herein.

In particular embodiments, the method as disclosed herein provides that a ligand compound is contacted with at least a part of the substrate together with the one or more metal precursor. In other words, an additional ligand may be added to the reaction chamber to improve the efficiency of film formation or material deposition. In some embodiments, the ligand may interact with the surface of the substrate to inhibit or promote chemisorption of the metal precursor to the surface. In some embodiments, the ligand may interact with the nitrogen reactant to improve the reaction rate between the chemisorbed metal and nitrogen reactant. In some embodiments, the ligand may interact with active surface sites on the substrate to render less active or inactive, i.e. poison, those surface sites.

In some preferred embodiments, the method as disclosed herein provides that the ligand compound is chosen from the group including at least one of XN(R¹⁶)₂, and beta-diketone; wherein X is hydrogen or an alkali metal chosen from the group consisting of Li, Na, K, and Rb; and wherein R¹⁶ is chosen from the group consisting of alkyl, and Si(R¹⁷)₃; and wherein R¹⁷ is chosen from the group consisting of alkyl, alkenyl, and alkoxy.

In some embodiments, the present disclosure provides that R¹⁶ is chosen from the group consisting of C₁₋₈alkyl, and Si(R¹⁷)₃; and wherein R¹⁷ is chosen from the group consisting of C₁₋₈alkyl, C₂₋₈alkenyl, and C₁₋₈alkoxy.

In some embodiments, the present disclosure provides that R¹⁶ is chosen from the group consisting of C₁₋₄alkyl, and Si(R¹⁷)₃; and wherein R¹⁷ is chosen from the group consisting of C₁₋₄alkyl, C₂₋₄alkenyl, and C₁₋₄alkoxy.

In some embodiments, the present disclosure provides that the ligand compound is dialkyldisilazane, or a salt thereof. In some embodiments, the present disclosure provides that the ligand compound is chosen from the group consisting of acetylacetonate, 2,2,6,6-tetramethylheptane-3,5-dionate, and 1,1,1,5,5,5-hexafluoropentane-2,4-dionate.

In particular embodiments, preferably wherein the metal precursor is a metal bis (arene) precursor, the present disclosure provides that the cycle further comprises a step of providing an organic molecule reactant into the reaction chamber, which comprises at least one halogen group, prior to or subsequent to providing the nitrogen reactant. The organic molecule reactant is able to react or interact with the metal precursor, resulting in a more reactive metal coordination complex which promotes reaction with a nitrogen reactant and/or oxygen reactant.

In particular embodiments, the method as disclosed herein provides that the organic molecule reactant is chosen from the group of formula (V) wherein

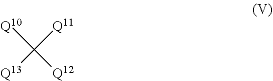

Q¹⁰, Q¹¹, Q¹², Q¹³ are each independently chosen from the group consisting of hydrogen, halogen, alkyl, alkenyl, cycloalkyl, aryl, alkylaryl, arylalkyl, alkoxy, and heteroalkyl; and wherein at least one of Q¹⁰, Q¹¹, Q¹², Q¹³ is halogen.

In some embodiments, the present disclosure provides that Q¹⁰, Q¹¹, Q¹², Q¹³ are each independently chosen from the group consisting of hydrogen, halogen, C₁₋₈alkyl, C₁₋₈alkenyl, C₃₋₈cycloalkyl, C₆₋₁₀aryl, C₁₋₈alkylC₆₋₁₀aryl, C₆₋₁₀arylC₁₋₈alkyl, C₁₋₈alkoxy, and heteroC₁₋₈alkyl; and wherein at least one of Q¹⁰, Q¹¹, Q¹², Q¹³ is halogen.

In some embodiments, the present disclosure provides that Q¹⁰, Q¹¹, Q¹², Q¹³ are each independently chosen from the group consisting of hydrogen, halogen, C₁₋₄alkyl, C₁₋₄alkenyl, C₃₋₈cycloalkyl, C₆₋₁₀aryl, C₁₋₄alkylC₆₋₁₀aryl, C₆₋₁₀arylC₁₋₄alkyl, C₁₋₄alkoxy, and heteroC₁₋₄alkyl; and wherein at least one of Q¹⁰, Q¹¹, Q¹², Q¹³ is F, Cl, Br, or I.

In particular embodiments, the method as disclosed herein provides that the organic molecule reactant is chosen from the group consisting of chloromethane (CH₃Cl), bromomethane (CH₃Br), iodomethane (CH₃I), dichloromethane (CH₂Cl₂), dibromomethane (CH₂Br₂), diiodomethane (CH₂I₂), trichloromethane (CHCl₃), tribromomethane (CHBr₃), triiodomethane (CHI₃), chloroethane (C₂H₅Cl), bromoethane (C₂H₅Br), iodoethane (C₂H₅I), 1,2-dichloroethane (C₂H₄Cl₂), 1,2-dibromoethane (C₂H₄Br₂), 1,2-diiodoethane (C₂H₄I₂), chloropropane (C₃H₇Cl), bromopropane (C₃H₇Br), iodopropane (C₃H₇I), 1,3-dichloropropane (C₃H₆Cl₂), 1,3-dibromopropane (C₃H₆Br₂), 1,3-diiodopropane (C₃H₆I₂), chlorobutane (C₄H₉Cl), bromobutane (C₄H₉Br), iodobutane (C₄H₉I), 1,4-dichlorobutane (C₄H₈Cl₂), 1,4-dibromobutane (C₄H₈Br₂), 1,4-diiodobutane (C₄H₈I₂), benzyl chloride (C₇H₇Cl), benzyl bromide (C₇H₇Br), benzyl iodide (C₇H₇I), chlorobenzene (C₆H₅Cl), bromobenzene (C₆H₅Br), and iodobenzene (C₆H₅I).

It shall be understood that the following embodiments can apply to any one of the methods disclosed herein, irrespective of the precursor and/or reactant that is used in such methods, unless a corresponding embodiment would render the method in question unworkable.

In some embodiments, the metal nitride containing film is deposited at a temperature of at least 100° C. to at most 500° C., or at a temperature of at least 200° C. to at most 450° C., or at a temperature of at least 300° C. to at most 400° C., or at a temperature of at least 350° C. to at most 450° C.

In some embodiments, the metal precursor is provided to the reaction chamber from a precursor source maintained at a temperature of at least 25° C. to at most 200° C., or at a temperature of at least 50° C. to at most 150° C., or at a temperature of at least 75° C. to at most 125° C.

In some embodiments, the nitrogen reactant is provided to the reaction chamber from a nitrogen source maintained at a temperature of at least 25° C. to at most 200° C., or at a temperature of at least 50° C. to at most 150° C., or at a temperature of at least 75° C. to at most 125° C.

In some embodiments, the oxygen reactant is provided to the reaction chamber from an oxygen source maintained at a temperature of at least 25° C. to at most 200° C., or at a temperature of at least 50° C. to at most 150° C., or at a temperature of at least 75° C. to at most 125° C.

In some embodiments, the metal and nitrogen containing film is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

The metal and nitrogen containing film can be deposited in any suitable reactor. Thus, in some embodiments, the metal and nitrogen containing film is deposited in a cross-flow reactor. In some embodiments, the metal and nitrogen containing film is deposited in a showerhead reactor. In some embodiments, the metal and nitrogen containing film is deposited in a hot-wall reactor. In some embodiments, the metal and nitrogen containing film is deposited in a cold-wall reactor. Doing so can advantageously enhance uniformity and/or repeatability of metal and nitrogen containing film deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the metal precursor is provided to the reaction chamber from a temperature-controlled precursor vessel. In some embodiments, the temperature-controlled precursor vessel is configured for cooling the precursor. In some embodiments, the temperature-controlled precursor vessel is configured for heating the precursor. In some embodiments, the temperature controlled precursor vessel is maintained at a temperature of at least −50° C. to at most 20° C., or at a temperature of at least 20° C. to at most 250° C., or at a temperature of at least 100° C. to at most 200° C.

In some embodiments, the metal precursor is provided to the reaction chamber by means of a carrier gas. Exemplary carrier gasses include nitrogen (N₂) and a noble gas such as He, Ne, Ar, Xe, or Kr.

In particular embodiments, the method as disclosed herein further comprises the step of forming a high-κ dielectric on the dipole layer. The high-κ dielectric has a dielectric constant larger than the dielectric constant of silicon oxide such as higher than about 7. Exemplary high-κ dielectrics include hafnium oxide (HfO₂), tantalum oxide (Ta₂O₅), zirconium oxide (ZrO₂), titanium oxide (TiO₂), hafnium silicate (HfSiOₓ), aluminium oxide (Al₂O₃) or lanthanum oxide (La₂O₃), mixtures thereof, and laminates thereof. The method as disclosed herein may further comprise the step of forming a conductive layer on the high-κ dielectric. The further conductive layer may comprise a nitride, such as silicon nitride, or a metal, such as aluminium, copper, or cobalt. In some embodiments, the semiconductor structure may comprise the following sequence of layers, in the order given: a SiO₂, the grown dipole layer, a high-κ dielectric layer, and a conductive layer.

In some preferred embodiments, the present disclosure relates to a field effect transistor (FET) comprising
a substrate;
a gate dielectric comprising a high-κ dielectric layer deposited on the surface of the substrate;
a dipole layer, comprising a metal nitride film and/or a metal oxynitride film, deposited on the surface of the substrate or high-κ dielectric layer; wherein
the gate dielectric has an equivalent oxide thickness (EOT) between at least 0.1 nm and at most 10 nm, or between at least 0.1 nm and at most 5 nm, or between at least 0.1 nm and at most 2 nm, or between at least 0.1 nm and at most 1.0 nm.

In some embodiments, the field effect transistor (FET) as disclosed herein has a gate leakage current of at most 0.5 pA/μm, or at most 0.4 pA/μm, or at most 0.3 pA/μm, or at most 0.2 pA/μm, preferably at most 0.1 pA/μm. In some embodiments, the field effect transistor (FET) as disclosed herein has a gate leakage current of at most 0.5 aA/μm, or at most 0.4 aA/μm, or at most 0.3 aA/μm, or at most 0.2 aA/μm, preferably at most 0.1 aA/μm. In some embodiments, the field effect transistor (FET) as disclosed herein has a gate leakage current of at most 0.5 zA/μm, or at most 0.4 zA/μm, or at most 0.3 zA/μm, or at most 0.2 zA/μm, preferably at most 0.1 zA/μm. Advantageously, as opposed to what is disclosed in the state of the art, the field effect transistor (FET) as disclosed herein is characterized by both a low leakage current and fast operation, which leads to energy-efficient electronic devices with high performance.

Preferably, the optional high-κ dielectric layer deposited on the surface of the substrate is chosen from hafnium oxide (HfO₂), tantalum oxide (Ta₂O₅), zirconium oxide (ZrO₂), titanium oxide (TiO₂), hafnium silicate (HfSiOₓ), aluminium oxide (Al₂O₃) or lanthanum oxide (La₂O₃), or mixtures thereof.

In some embodiments, the field effect transistor (FET) as disclosed herein may further comprise a second high-κ dielectric deposited on the dipole layer. In some embodiments, the field effect transistor (FET) as disclosed herein may further comprise a conductive layer deposited on the second high-κ dielectric. Preferably, the further conductive layer may comprise a nitride, such as silicon nitride, or a metal, such as aluminium, copper, or cobalt.

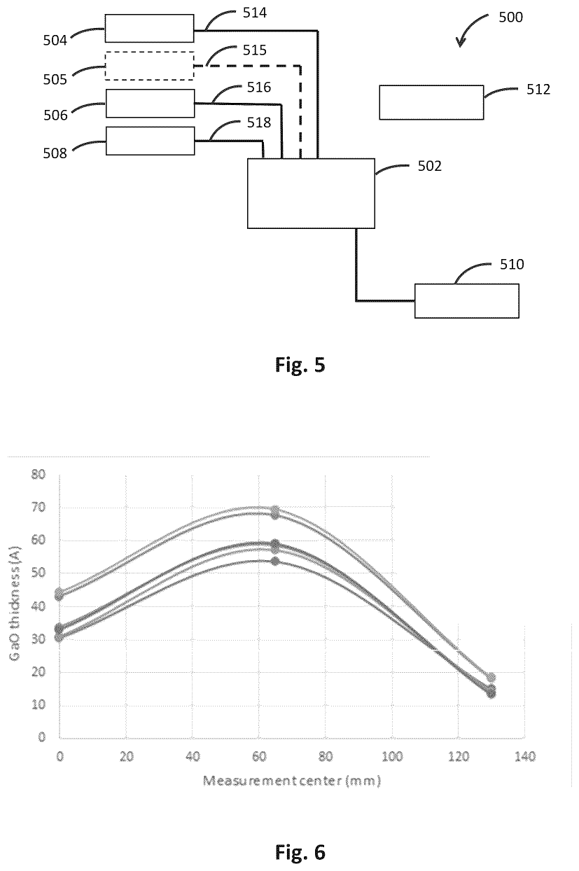

In some preferred embodiments, the present disclosure relates to a system, wherein the system is configured to perform the method as disclosed herein. FIG. 5 illustrates a system (500) in accordance with such exemplary embodiments. In the illustrated example, the system (500) includes one or more reaction chambers (502), a metal precursor gas source (504), a nitrogen reactant gas source (506), a purge gas source (508), an exhaust (510), and a controller (512). The reaction chamber (502) can include any suitable reaction chamber, such as an ALD or CVD reaction chamber. Optionally, the system (500) comprises further gas sources such as an optional oxygen reactant containing gas source (505).

The subject matter of the present disclosure includes all novel and nonobvious combinations and subcombinations of the various processes, systems, and configurations, and other features, functions, acts, and/or properties disclosed herein, as well as any and all equivalents thereof.

As an exemplary embodiment, the method as disclosed herein may be performed using a system according to FIG. 5 as described herein. According to the embodiment, the metal precursor pulse may comprise GaMe₃ and the nitrogen reactant pulse may comprise NH₃. The following preferred parameters may be used during material deposition in the system (500):
Substrate temperature: 160° C.
Pressure in the reaction chamber: 8 Torr
Metal precursor pulse (GaMe₃): 100-150 ms
Purge time after metal precursor pulse: 40 000 ms
Nitrogen reactant pulse (NH₃): 10 000 ms
Purge time after nitrogen reactant pulse: 40 000 ms
Amount of cycles: 400

As shown in FIG. 6 a formed GaN film is not etchable by TiCl₄ or NH₃ treatment.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

1. A method for forming a semiconductor structure comprising a dipole layer, the method comprising the steps of:
a) providing a substrate to a reaction chamber;
b) executing one or more cycles, a cycle comprising
i. contacting one or more metal precursor with at least a part of the substrate by introducing the one or more metal precursor in the reaction chamber; and
ii. providing a nitrogen reactant into the reaction chamber,
thereby forming a metal and nitrogen containing film on at least part of the substrate.

2. The method according to claim 1, wherein the substrate comprises at least one of an interlayer and a high-k layer, wherein the method further comprises a step of annealing the substrate, thereby forming a dipole layer.

3. The method according to claim 1, wherein the cycle further comprises a step of providing an oxygen reactant into the reaction chamber, thereby forming a metal, oxygen, and nitrogen containing film on at least part of the substrate.

4. The method according to claim 1, wherein the one or more metal precursor comprises an element chosen from the group consisting of Mg, Ca, Sr, Ba, Al, Ga, In, Sc, Y, La, Ce, Pr, Nd, Pm, Sm, Eu, Gd, Tb, Dy, Ho, Er, Tm, Yb, Lu, Ti, Zr, Hf, V, Nb, Ta, Cr, Mo, Re, Ge, Sb, Zn, and W.

5. The method according to claim 1, wherein the one or more metal precursor comprises a ligand chosen from the group consisting of an amine, alkenyl, carbonyl, alkoxide, beta-diketone, diazadiene, amidinate, halogen, guanidinate, triazenide, carboxylate, cyclopentadienyl, and/or aryl.

6. The method according to claim 1, wherein the one or more metal precursor comprises a metal element chosen from the group including at least one of Ga and W.

7. The method according to claim 6, wherein the metal element is tungsten (W) and the one or more metal precursor is chosen from the group including at least one of formula (I), formula (II), and formula (III) 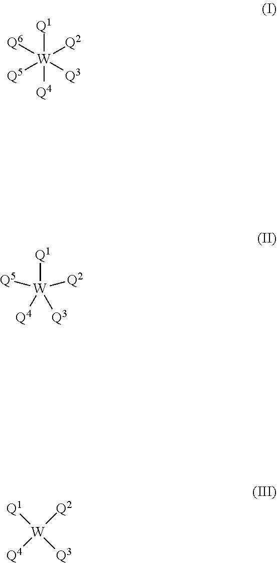
wherein Q¹, Q², Q³, Q⁴, Q⁵, Q⁶ are each independently chosen from the group consisting of CO, F, Cl, Br, I, alkyl, alkenyl, N(R¹)₂, alkoxy, cycloalkoxy, cycloalkyl, aryl, arylalkyl, alkylaryl, cyclopentadienyl, alkyl-substituted cyclopentadienyl, and heteroalkyl, and
wherein each R¹ is independently chosen from the group consisting of hydrogen, alkyl, cycloalkyl, aryl, arylalkyl, alkylaryl, and heteroalkyl.

8. The method according to claim 6, wherein the metal element is tungsten (W) and the one or more metal precursor is chosen from the group consisting of WF₆, WCl₆, WBr₆, WI₆, W(CO)₆, WF₂(CO)₄, WCl₂(CO)₄, WBr₂(CO)₄, W(Me)₆, W(Et)₆, W(nPr)₆, W(nBu)₆, W(tBu)₆, W(NME₂)₆, W(NtBu)₂(NMe₂)₄, W(NEt₂)₆, W(acac)₂(CO)₄, W(acac)₁(CO)₅, W(acac)₃(CO)₃, W(Pyr)₆, W(benzene)(CO)₅, W(toluene)(CO)₅, W(cyclopentadienyl)(CO)₅, W(naphthalene)(CO)₅, WF₅, WCl₅, WBr₅, WI₅, W(CO)₅, WF₂(CO)₃, WCl₂(CO)₃, WBr₂(CO)₃, W(Me)₅, W(Et)₅, W(nPr)₅, W(nBu)₅, W(tBu)₅, W(NME₂)₅, W(NtBu)₂(NMe₂)₃, W(NEt₂)₅, W(acac)₂(CO)₃, W(acac)₁(CO)₄, W(acac)₃(CO)₂, W(Pyr)₅, W(benzene)(CO)₄, W(toluene)(CO)₄, W(cyclopentadienyl)(CO)₄, W(naphthalene)(CO)₄, WF₄, WCl₄, WBr₄, WI₄, W(CO)₄, WF₂(CO)₂, WCl₂(CO)₂, WBr₂(CO)₂, W(Me)₄, W(Et)₄, W(nPr)₄, W(nBu)₄, W(tBu)₄, W(NME₂)₄, W(NtBu)₂(NMe₂)₂, W(NEt₂)₄, W(acac)₂(CO)₂, W(acac)₁(CO)₃, W(acac)₃(CO)₁, W(Pyr)₄, W(benzene)(CO)₃, W(toluene)(CO)₃, W(cyclopentadienyl)(CO)₃, and W(naphthalene)(CO)₃.

9. The method according to claim 6, wherein the metal element is gallium (Ga) and the one or more metal precursor is chosen from the group of formula (IV) 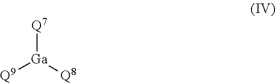
wherein Q⁷, Q⁸, Q⁹ are each independently chosen from the group consisting of F, Cl, Br, I, alkyl, alkenyl, N(R²)₂, alkoxy, cycloalkoxy, cycloalkyl, aryl, arylalkyl, alkylaryl, R³NC(R⁴)NR⁵, R⁶NC[N(R⁷)₂]NR⁸, R⁹N₃R¹⁰, cyclopentadienyl, alkyl-substituted cyclopentadienyl, and heteroalkyl, and
wherein each R², R³, R⁴, R⁵, R⁶, R⁷, R⁸, R⁹, R¹⁰ is independently chosen from the group consisting of hydrogen, alkyl, cycloalkyl, aryl, arylalkyl, alkylaryl, and heteroalkyl.

10. The method according to claim 6, wherein the metal element is gallium (Ga) and the one or more metal precursor is chosen from the group consisting of GaF₃, GaCl₃, GaBr₃, GaI₃, Ga(Me)₃, Ga(Et)₃, Ga(nPr)₃, Ga(nBu)₃, Ga(tBu)₃, Ga(NMe₂)₃, Ga(NtBu)₂(NMe₂)₁, Ga(NtBu)₁(NMe₂)₂, Ga(NEt₂)₃, Ga(Pyr)₃, Ga(guanidinate)₃, and Ga(triazenide)₃.

11. The method according to claim 1, wherein the nitrogen reactant is chosen from the group consisting of N(R¹¹)₃, and (R¹²)NN(R¹³); wherein each R¹¹, R¹², R¹³ is independently chosen from the group consisting of hydrogen, alkyl, alkenyl, cycloalkyl, and Si(R¹⁴)₃; wherein R¹⁴ is chosen from the group consisting of alkyl, alkenyl, alkoxy and Si(R¹⁵)₃; and wherein R¹⁵ is chosen from the group consisting of alkyl, alkenyl, and alkoxy.

12. The method according to claim 1, wherein the nitrogen reactant is selected from the group including at least one of NH₃, diazene (N₂H₂), hydrazine (N₂H₄), methylhydrazine (N₂MeH₃), ethylhydrazine (N₂EtH₃), propylhydrazine (N₂nPrH₃), butylhydrazine (N₂nBuH₃), tert-butylhydrazine (N₂tBuH₃), 1,1-dimethylhydrazine (N₂Me₂H₂), 1,1-diethylhydrazine (N₂Et₂H₂), 1,1-dipropylhydrazine (N₂nPr₂H₂), 1,1-dibutylhydrazine (N₂nBu₂H₂), trimethylsilylhydrazine (N₂[Si(Me)₃]H₂), and tris(trimethylsilyl)silylhydrazine (N₂[Si(Si(Me)₃)₃]H₂).

13. The method according to claim 3, wherein the oxygen reactant is chosen from the group including at least one of H₂O, D₂O, H₂O₂, O₃, O₂, N₂O, NO, N₂O₅, SO₂, oxygen-containing plasma, and oxygen radicals.

14. The method according to claim 1, wherein the metal and nitrogen containing film comprises at least one of Galium Nitride (GaN) and Tungsten Nitride (WN).

15. The method according to claim 3, wherein the metal, oxygen, and nitrogen containing film comprises at least one of Gallium Oxynitride (GaON) and Tungsten Oxynitride (WON).

16. The method according to claim 1, wherein a ligand compound is contacted with at least a part of the substrate together with the one or more metal precursor.

17. The method according to claim 16, wherein the ligand compound is chosen from the group including at least one of XN(R¹⁶)₂, and beta-diketone; wherein X is hydrogen or an alkali metal chosen from the group consisting of Li, Na, K, and Rb; and wherein R¹⁶ is chosen from the group consisting of alkyl, and Si(R¹⁷)₃; and wherein R¹⁷ is chosen from the group consisting of alkyl, alkenyl, and alkoxy.

18. The method according to claim 16, wherein the ligand compound is dialkyldisilazane, or a salt thereof.

19. The method according to claim 16, wherein the ligand compound is chosen from the group consisting of acetylacetonate, 2,2,6,6-tetramethylheptane-3,5-dionate, and 1,1,1,5,5,5-hexafluoropentane-2,4-dionate.
